(19) United States
(12) Patent Application Publication
(10) Pub. No.: US 2011/0192439 A1
(43) Pub. Date: Aug. 11, 2011

(54) THERMOELECTRIC ARRAY

(75) Inventors: Young Sam PARK, Daejeon (KR); Moon Gyu Jang, Daejeon (KR); Myung Sim Jun, Daejeon (KR); Young Hoon Hyun, Seoul (KR)

(73) Assignee: ELECTRONICS AND TELECOMMUNICATIONS RESEARCH INSTITUTE, Daejeon (KR)

(21) Appl. No.: 13/022,251

(22) Filed: Feb. 7, 2011

(30) Foreign Application Priority Data
Feb. 8, 2010 (KR) 10-2010-0011284

(51) Int. Cl. H01L 35/30

(52) U.S. Cl. 136/212

(57) ABSTRACT

Provided is a thermoelectric array including a plurality of thermoelectric elements arranged in m rows and n columns (each of m and n is an integer equal to or more than 1), each thermoelectric element including a heat absorption layer, a first heat sink layer, a second heat sink layer, a first-conductivity-type leg, and a second-conductivity-type leg formed on the same plane. The heat absorption layers of the thermoelectric elements adjacently disposed in a row or column direction are disposed adjacent to each other, and the first and second heat sink layers of the adjacent thermoelectric elements are disposed adjacent to each other. In this case, thermal interference between adjacent thermoelectric elements may be minimized, thereby obtaining a thermoelectric array having a high figure of merit.

### CROSS-REFERENCE TO RELATED APPLICATION

This application claims priority to and the benefit of Korean Patent Application No. 10-2010-0011284, filed Feb. 8, 2010, the disclosure of which is incorporated herein by reference in its entirety.

### BACKGROUND

1. Field of the Invention

The present invention relates to a thermoelectric array including a plurality of thermoelectric elements and, more particularly, to a thermoelectric array structured to minimize thermal interference between thermoelectric elements to improve the figure of merit.

2. Discussion of Related Art

In recent years, thermoelectric elements configured to convert heat energy into electric energy have attracted much attention due to a clean-energy-oriented policy.

A thermoelectric effect was discovered by Thomas Seebeck in the 1800's. Seebeck connected bismuth (Bi) and copper (Cu) and disposed a compass therebetween. Seebeck demonstrated that when heating one side of the Bi, current was induced due to a temperature difference and the compass moved due to a magnetic field caused by the induced current, to demonstrate the thermoelectric effect for the first time.

FIG. 1 is a diagram of a typical thermoelectric element.

Referring to FIG. 1, a thermoelectric element 100 may include a heat absorption layer 110, a leg 130, and a heat sink layer 150, and the leg 130 may include an n-type leg 131 and a p-type leg 133.

The heat absorption layer 110 may serve to absorb heat from an external heat source, and the leg 130 may transmit the heat absorbed into the heat absorption layer 110 to the heat sink layer 150. The heat sink layer 150 may serve to externally emit the heat transmitted by the leg 130.

Due to a temperature difference between the heat absorption layer 110 and the heat sink layer 150, electrons may move from the heat absorption layer 110 toward the heat sink layer 150 in the n-type leg 131, while holes move from the heat absorption layer 110 toward the heat sink layer 150 in the p-type leg 133. Thus, current may flow counterclockwise due to the movement of the electrons and holes.

In order to improve the figure of merit of the thermoelectric element 100, the heat absorption layer 110 should maximize the heat absorbed from the external heat source and transmit all of the absorbed heat to the leg 130, and the leg 130 should transmit the heat transmitted by the heat absorption layer 110 as slowly as possible. Also, the heat sink layer 150 should not absorb heat from the external heat source at all but emit the heat transmitted by the leg 130 as much as possible.

That is, the temperature difference between the heat absorption layer 110 and the heat sink layer 150 should be as great as possible to improve the figure of merit.

A ZT value is a measure of the figure of merit of a thermoelectric element. The ZT value is proportional to the square of a Seebeck coefficient and electric conductivity and inversely proportional to thermal conductivity.

However, a thermoelectric element using a metal has a very low Seebeck coefficient of about several μV/K, and electric conductivity is proportional to thermal conductivity due to the Wiedemann-Franz law, so that the thermoelectric element using the metal cannot have a high ZT value.

To solve the above-described problem, thermoelectric elements using semiconductor materials have lately been developed. Typical semiconductor materials for the thermoelectric elements may be Bi₂Te₃ and SiGe. Bi₂Te₃ has a ZT value of 0.7 or more at room temperature and a ZT value of 0.9 or less at a temperature of about 120° C. SiGe has a ZT value of 0.1 or more at room temperature and a ZT value of 0.9 or less at a temperature of about 900° C. Furthermore, research has been conducted on substitute materials (e.g., silicon (Si)) for Bi₂Te₃.

Meanwhile, since a single thermoelectric element cannot satisfy market requirements, currently commercialized thermoelectric products have the types of thermoelectric arrays in which at least two thermoelectric elements are electrically connected to one another.

FIG. 2 is a diagram of a conventional thermoelectric array using a vertical thermoelectric element.

In a thermoelectric array 200 of FIG. 2, heat absorbed into an uppermost heat absorption layer 210 may be transmitted through the leg 230 to a lowermost heat absorption layer 250.

A high figure of merit can be expected from the thermoelectric array 200 having the above-described construction because it is unlikely that heat absorbed into the heat absorption layer 210 will be directly transmitted to the heat sink layer 250 without passing through the leg 230.

Meanwhile, in the conventional thermoelectric array 200, the thermoelectric element is arranged in a vertical direction. Thus, manufacture of the thermoelectric array 200 may involve separately manufacturing a substrate including the heat absorption layer 210, a substrate including the heat sink layer 250, and the leg 230 and assembling the thermoelectric array 200 by interposing the leg 230 in a vertical direction between the substrate including the heat absorption layer 210 and the substrate including the heat sink layer 250. Accordingly, since the substrate including the heat absorption layer 210, the substrate including the heat sink layer 250, and the leg 230 should be separately manufactured and then assembled into the conventional thermoelectric array 200, manufacturing costs may be greatly increased.

### SUMMARY OF THE INVENTION

The present invention is directed to a thermoelectric array having a new structure, which can improve a figure of merit and reduce manufacturing costs.

One aspect of the present invention provides a thermoelectric array including a plurality of thermoelectric elements arranged in m rows and n columns (each of m and n is an integer equal to or more than 1), each thermoelectric element including a heat absorption layer, a first heat sink layer, a second heat sink layer, a first-conductivity-type leg, and a second-conductivity-type leg formed on the same plane. Heat the absorption layers of the thermoelectric elements adjacently disposed in a row or column direction are disposed adjacent to each other, and the first and second heat sink layers of the thermoelectric elements adjacently disposed in a row or column direction are disposed adjacent to each other.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a diagram of a typical thermoelectric element;

FIG. 2 is a diagram of a conventional thermoelectric array using vertical thermoelectric elements;

FIGS. 3A and 3B are top views of a thermoelectric array according to a first exemplary embodiment of the present invention;

FIGS. 4A and 4B are top views of a thermoelectric array according to a second exemplary embodiment of the present invention; and

FIGS. 5A and 5B are top views of a thermoelectric array according to a third exemplary embodiment of the present invention.

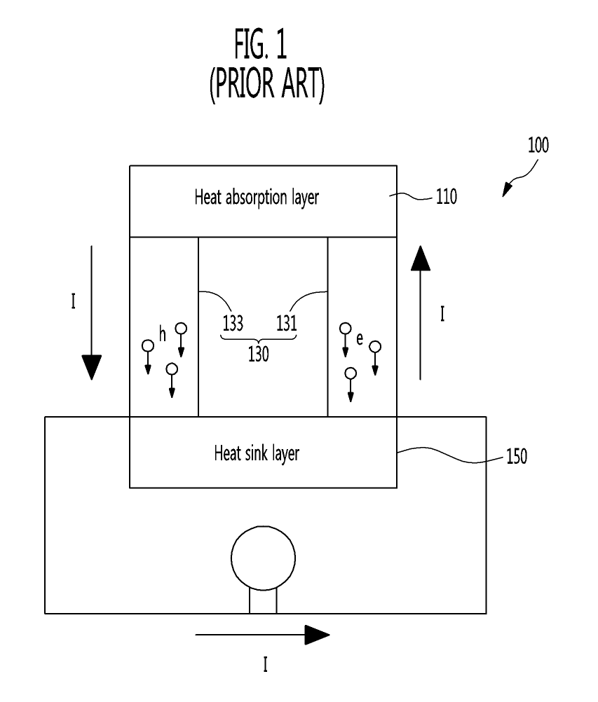

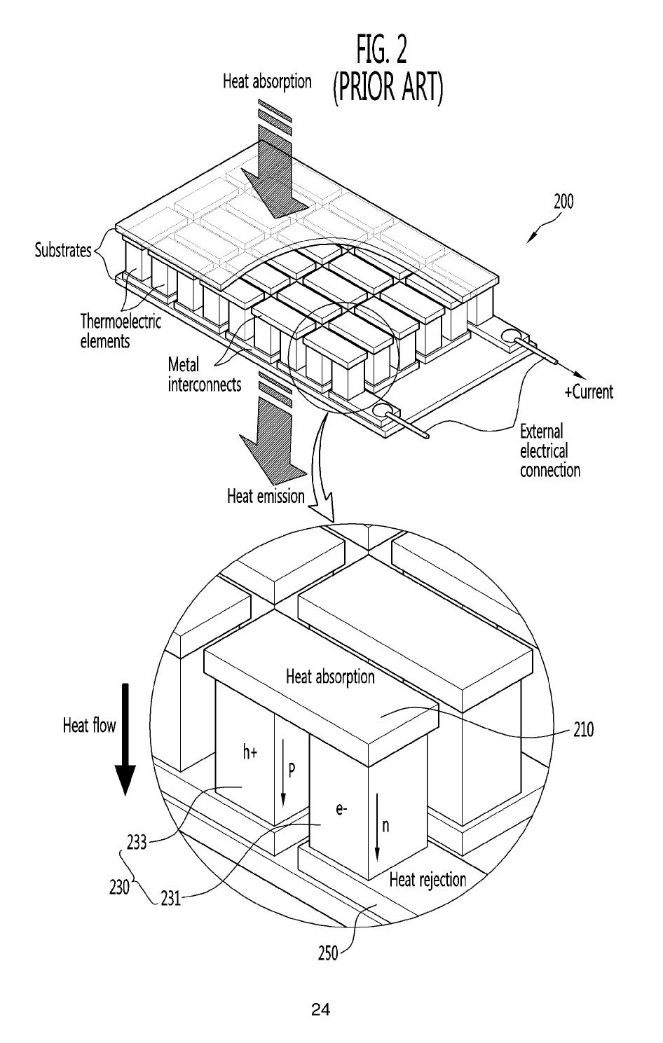

### DETAILED DESCRIPTION OF EMBODIMENTS

The objects, features, and advantages of the present invention will be apparent from the following detailed description of embodiments of the invention with references to the following drawings. Descriptions of well-known components and processing techniques are omitted so as not to unnecessarily obscure the embodiments of the present invention. The present invention will now be described more fully with reference to the accompanying drawings, in which exemplary embodiments of the invention are shown.

Initially, principle concepts of the present invention will briefly be described.

A thermoelectric array includes at least two thermoelectric elements electrically connected to one another. To improve the figure of merit of the thermoelectric array, thermal interference between adjacent thermoelectric elements should be minimized.

In each of the thermoelectric elements, when heat absorbed into a heat absorption layer from an external heat source is transmitted to a heat sink layer of an adjacent thermoelectric element without passing through a leg, a temperature difference between the heat absorption layer of the corresponding thermoelectric element and the heat sink layer of the adjacent thermoelectric element is sharply reduced, so that a ZT value, which is a measure of the figure of merit, can be greatly reduced.

Therefore, the present invention provides a newly-configured thermoelectric array in which heat absorption layers of adjacent thermoelectric elements may be disposed adjacent to each other, and heat sink layers of the adjacent thermoelectric elements may be disposed adjacent to each other to minimize thermal interference between the thermoelectric elements.

Furthermore, according to the present invention, a heat absorption layer, a leg, and a heat sink layer of a thermoelectric element may be simultaneously formed using a semiconductor process, thereby reducing manufacturing costs.

The above-described features will be understood more readily with reference to the following embodiments.

### Embodiment 1

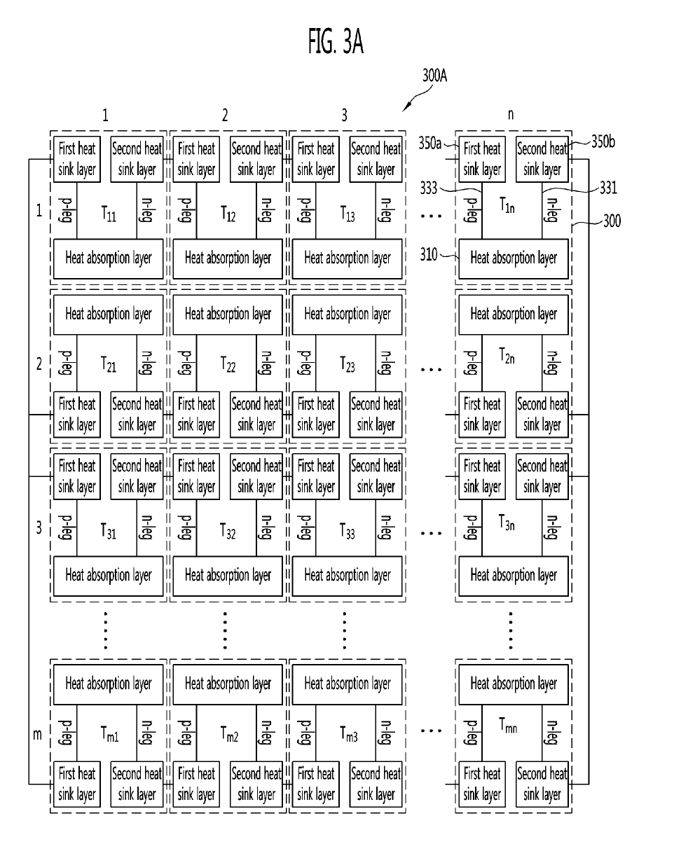

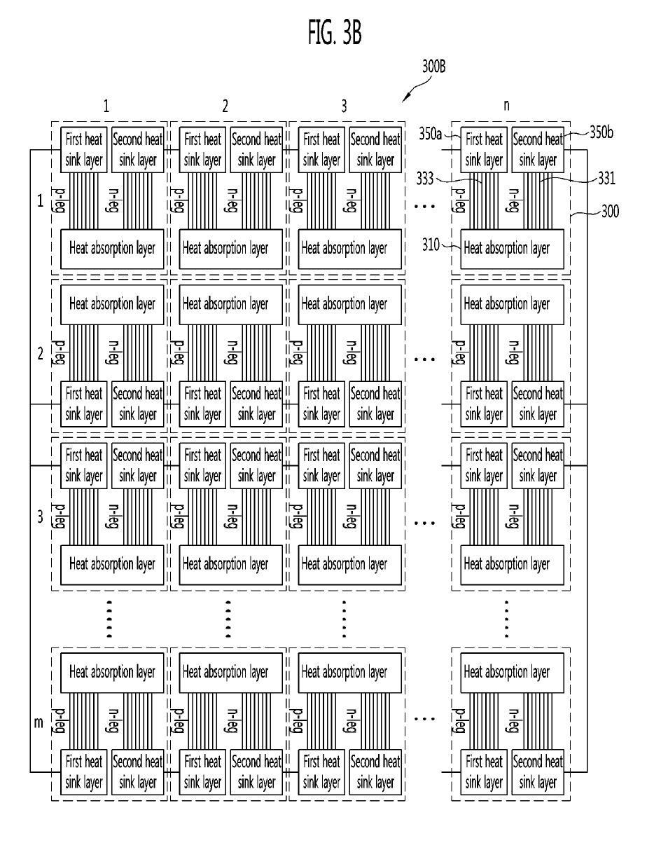

FIGS. 3A and 3B are top views of a thermoelectric array according to a first embodiment of the present invention.

To begin with, referring to FIG. 3A, a thermoelectric array 300A according to the first embodiment may include a plurality of thermoelectric elements 300 arranged in m rows and n columns (here, each of m and n is an integer equal to or more than 1). Each of the thermoelectric elements 300 may include a heat absorption layer 310, an n-type leg 331, a p-type leg 333, and first and second heat sink layers 350a and 350b. The heat absorption layers 310 of the thermoelectric elements 300 adjacently disposed in a row or column direction may be arranged adjacent to one another, and the heat sink layers 350a and 350b of the adjacent thermoelectric elements 300 in a row or column direction may be arranged adjacent to one another.

For brevity, in FIG. 3A, the respective thermoelectric elements 300 arranged in rows and columns are denoted by T₁₁, T₁₂, . . . , and Tₘₙ.

The thermoelectric array 300A shown in FIG. 3A may be characterized in that (1) thermal interference between the thermoelectric elements 300 is minimized, (2) the heat absorption layer 310, the n- and p-type legs 331 and 333, and the heat sink layers 350a and 350b included in each of the thermoelectric elements can be simultaneously formed, and (3) power can be controlled by adjusting the numbers of rows and columns of the thermoelectric elements 300, which will now be described in further detail.

### (1) Inhibition of Thermal Interference Between Thermoelectric Elements

Each of the thermoelectric elements 300 may include the heat absorption layer 310, the first heat sink layer 350a, the second heat sink layer 350b, the p-leg 333, and the n-leg 331. Here, the heat absorption layer 310 may be spaced a predetermined distance apart from and opposite the heat sink layers 350a and 350b. Also, the p-leg 333 may be provided between the heat absorption layer 310 and the first heat sink layer 350a, and the n-leg 331 may be provided between the heat absorption layer 310 and the second heat sink layer 350b so that the heat absorption layer 310 can be connected to the heat sink layers 350a and 350b.

Each of the thermoelectric elements 300 having the above-described structure may be arranged in the shape of a matrix of m rows and n columns and characterized by the following two points.

First, in a plurality of thermoelectric elements 300 included in one row, the heat absorption layer 310 may be disposed at one side of each of the thermoelectric elements 300, while the heat sink layers 350a and 350b may be disposed at the other side thereof. Here, the first heat sink layers 350a and second heat sink layers 350b of the thermoelectric elements 300 adjacently disposed in the row direction may be connected to each other. For example, the second heat sink layer 350b of a thermoelectric element T₁₁ disposed in a first row and a first column may be connected to the first heat sink layer 350a of a thermoelectric element T₁₂ disposed in a first row and a second column.

Second, adjacent rows may be disposed in a mirror type. For example, thermoelectric elements T₁₁ to T₁n included in the first row may be arranged in a mirror type with respect to thermoelectric elements T₂₁ to T₂n included in a second row, while the thermoelectric elements T₂₁ to T₂n included in a second row may be arranged in a mirror type with respect to thermoelectric elements T₃₁ to T₃n included in a third row.

When the adjacent rows are arranged in the mirror type, the integration density of the thermoelectric elements 300 disposed on a substrate may be improved. Simultaneously, the heat absorption layers 310 may be disposed adjacent to each other, and the first heat sink layers 350a and the second heat sink layers 350b may be disposed adjacent to each other, while the heat absorption layer 310 may be spaced the farthest possible distance from the heat sink layers 350a and 350b, thereby minimizing thermal interference between the adjacent thermoelectric elements 300.

For example, a heat absorption layer 310 of a thermoelectric element T₂₂ disposed in a second row and a second column may be disposed adjacent to a heat absorption layer 310 of a thermoelectric element T₁₂ disposed in a first row and a second column, and heat sink layers 350a and 350b of the thermoelectric element T₂₂ may be disposed adjacent to heat sink layers 350a and 350b of a thermoelectric element T₃₂ disposed in a third row and a second column. Also, the heat absorption layer 310 of the thermoelectric element T₂₂ may be disposed adjacent to a heat absorption layer 310 of each of thermoelectric elements T₂₁ and T₂₃ disposed on both sides of the thermoelectric element T₂₂, and the heat sink layers 350a and 350b of the thermoelectric element T₂₂ may be disposed adjacent to heat sink layers 350a and 350b of each of the thermoelectric elements T₂₁ and T₂₃.

Due to the above-described arrangement, since the heat absorption layer 310 of the thermoelectric element T₂₂ disposed in the second row and the second column is spaced far apart from the heat sink layers 350a and 350b of the thermoelectric elements T₁₂, T₃₂, T₂₁, and T₂₃ disposed adjacently in all directions, heat absorbed into the heat absorption layer 310 of the thermoelectric element T₂₂ disposed in the second row and the second column may not be transmitted to the heat sink layers 350a and 350b of the adjacent thermoelectric elements T₁₂, T₃₂, T₂₁, and T₂₃. Also, the heat sink layers 350a and 350b of the thermoelectric element T₂₂ disposed in the second row and the second column may become spaced apart from the heat absorption layers 310 of the adjacent thermoelectric elements T₁₂, T₃₂, T₂₁, and T₂₃.

Accordingly, the thermoelectric array 300A may inhibit thermal interference between the adjacent thermoelectric elements 300 to improve the figure of merit.

### (2) Thermoelectric Elements Capable of Simultaneously Forming Heat Absorption Layer, Leg, and Heat Sink Layer

As described above, manufacture of a conventional thermoelectric array involves separately forming a heat absorption layer, a leg, and a heat sink layer of a thermoelectric element and assembling the heat absorption layer, the leg, and the heat sink layer, thereby necessitating a complicated manufacturing process and high manufacturing costs.

To overcome this drawback, the present invention provides a technique of simultaneously forming the heat absorption layer 310, the leg 331 and 333, and the heat sink layers 350a and 350b, which will now be described in further detail.

For brevity, a case where thermoelectric elements are formed on a silicon-on-insulator (SOI) substrate including a silicon semiconductor layer as an uppermost layer will be described.

Initially, the silicon semiconductor layer disposed in an uppermost portion of the SOI substrate may be etched, thereby forming first and second electrode patterns for a heat absorption layer and a heat sink layer and first and second leg patterns for n-type and p-type legs. Here, since the first and second electrode patterns and the first and second leg patterns are simultaneously formed by etching a single silicon semiconductor layer, a heat absorption layer, a heat sink layer, an n-type leg, and a p-type leg which will be formed in a subsequent process may be formed on the same plane.

Here, the first and second leg patterns may be formed in the form of nanowires having a width (or diameter) of about 100 nm or less.

Also, the etching process may be performed using an electronic-beam (e-beam) lithography technique, a sidewall forming technique, or an ordinary exposure technique.

Next, impurities may be implanted into the first and second leg patterns, thereby forming the n-type leg 331 and the p-type leg 333.

Specifically, the n-type leg 331 and the p-type leg 333 may be formed of a material containing at least one selected from the group consisting of silicon (Si), tellurium (Te), and oxygen (O). For example, the n-type leg 331 and the p-type leg 333 may be formed in the form of nanowires using Si, silicon germanium (SiGe), bismuth tellurium (BiTe), lead tellurium (PbTe), or an oxide-based material.

In this case, the implantation of the impurities may be performed using at least one selected from the group consisting of an ion-beam implantation process, a diffusion process, and a plasma process.

Next, a metal may be deposited on the first and second electrode patterns, thereby forming the heat absorption layer 310 and the heat sink layers 350a and 350b.

Specifically, the heat absorption layer 310 and the heat sink layers 350a and 350b may be formed of a material containing at least one selected from the group consisting of a doped semiconductor, a metal, and a metal compound.

Therefore, since the heat absorption layer 310, the leg 331 and 333, and the heat sink layer 350a and 350b of the thermoelectric element 300 may be formed on the same plane using a semiconductor processing technique, separately forming respective components and assembling the components may be unnecessary. Accordingly, the manufacturing costs of the thermoelectric array 300A may be reduced more than in the conventional case.

### (3) Control of Output Power

In the thermoelectric array 300A of FIG. 3A, an output voltage may be controlled by adjusting the number of the thermoelectric elements 300 included in each row, and an output current may be controlled by adjusting the number of the thermoelectric elements 300 included in each column.

In other words, output power of the thermoelectric array 300A may be controlled by adjusting the numbers of the thermoelectric elements 300 included in each row and each column.

Meanwhile, each of the thermoelectric elements 300 of the thermoelectric array 300A of FIG. 3A may include one n-type leg 331 and one p-type leg 333, while each of the thermoelectric elements 300 of the thermoelectric array 300B of FIG. 3B may include at least one n-type leg 331 and at least one p-type leg 333.

Furthermore, although the present embodiment describes an example case where the leg 331 and 333 of each of the thermoelectric elements 300 is disposed in a horizontal direction with respect to a substrate (not shown), it is also possible for the leg 331 and 333 to be disposed in a vertical direction to the substrate.

### Embodiment 2

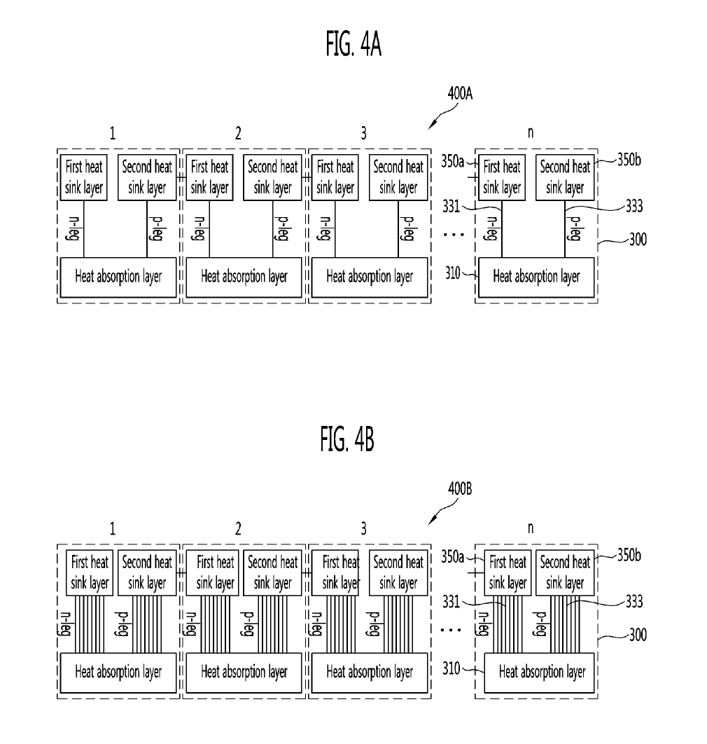

FIGS. 4A and 4B are top views of a thermoelectric array according to a second embodiment of the present invention.

To begin with, referring to FIG. 4A, a thermoelectric array 400A according to the second embodiment may include thermoelectric elements 300 arranged in one row and n columns (here, n is an integer equal to or more than 1).

Heat absorption layers 310 of adjacent thermoelectric elements 300 may be disposed adjacent to each other, and heat sink layers 350a and 350b of the adjacent thermoelectric elements 300 may be disposed adjacent to each other. Due to the above-described arrangement structure, thermal interference between adjacent thermoelectric elements 300 may be minimized.

Meanwhile, an output voltage of the thermoelectric array 400A of FIG. 4A may be controlled by adjusting the number of the thermoelectric elements 300 included in one row.

Also, each of the thermoelectric elements 300 of the thermoelectric array 400A shown in FIG. 4A includes one n-type leg 331 and one p-type leg 333, while each of thermoelectric elements 300 of a thermoelectric array 400B shown in FIG. 4B includes at least one n-type leg 331 and at least one p-type leg 333.

### Embodiment 3

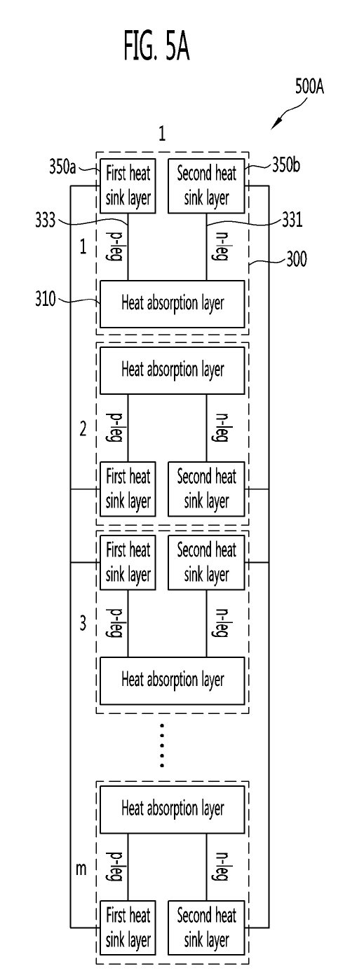

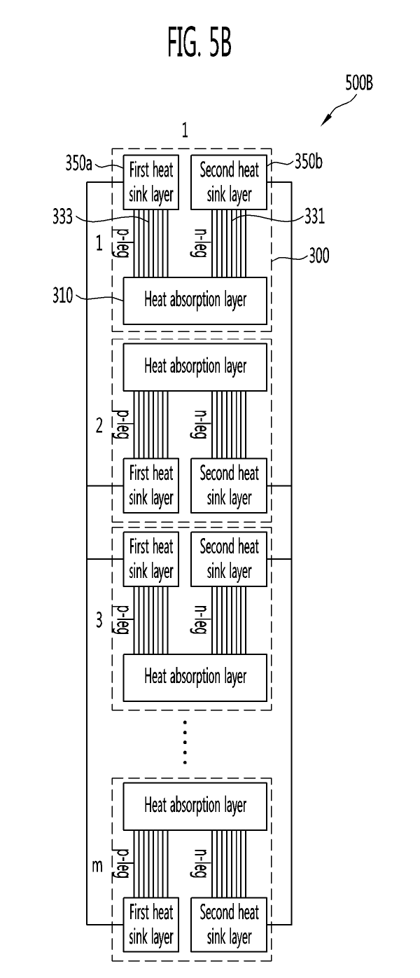

FIGS. 5A and 5B are top views of a thermoelectric array according to a third embodiment of the present invention.

To begin with, referring to FIG. 5A, a thermoelectric array 500A according to the third embodiment may include thermoelectric elements 300 arranged in m rows and one column (here, m is an integer equal to or more than 1).

Heat absorption layers 310 of adjacent thermoelectric elements 300 may be disposed adjacent to each other, and heat sink layers 350a and 350b of adjacent thermoelectric elements 300 may be disposed adjacent to each other. Due to the above-described arrangement, thermal interference between adjacent thermoelectric elements 300 may be minimized.

Meanwhile, an output current of the thermoelectric array 500A of FIG. 5A may be controlled by adjusting the number of the thermoelectric elements 300 included in one column.

Also, each of the thermoelectric elements 300 of the thermoelectric array 500A shown in FIG. 5A includes one n-type leg 331 and one p-type leg 333, while each of the thermoelectric elements 300 of FIG. 5B includes at least one n-type leg 331 and at least one p-type leg 333.

According to the present invention, since thermal interference between adjacent thermoelectric elements of a thermoelectric array may be minimized, the thermoelectric array can have a high figure of merit.

Furthermore, according to the present invention, a heat absorption layer, a leg, and a heat sink layer of a thermoelectric element can be simultaneously formed using a semiconductor process. Thus, the manufacturing costs of a thermoelectric array may be reduced more than in a conventional art in which a heat absorption layer, a leg, and a heat sink layer are separately formed and assembled into a thermoelectric array.

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A thermoelectric array comprising a plurality of thermoelectric elements arranged in m rows and n columns (each of m and n is an integer equal to or more than 1), each thermoelectric element including a heat absorption layer, a first heat sink layer, a second heat sink layer, a first-conductivity-type leg, and a second-conductivity-type leg formed on the same plane,
wherein the heat absorption layers included in thermoelectric elements adjacently disposed in a row or column direction are disposed adjacent to each other, and the first and second heat sink layers included in the adjacent thermoelectric elements are disposed adjacent to each other.

2. The array of claim 1, wherein the first and second heat sink layers included in each of the thermoelectric elements are spaced apart from and disposed opposite the heat absorption layer, the first-conductivity-type leg is disposed between the heat absorption layer and the first heat sink layer, and the second-conductivity-type leg is disposed between the heat absorption layer and the second heat sink layer.

3. The array of claim 2, wherein the thermoelectric elements included in one row are arranged in a mirror type with respect to the thermoelectric elements included in adjacent rows.

4. The array of claim 2, wherein the thermoelectric elements included in one row are arranged such that the heat absorption layer is disposed at one side of each of the thermoelectric elements and the first and second heat sink layers are disposed at the other side thereof.

5. The array of claim 1, wherein the heat absorption layer, the first heat sink layer, the second heat sink layer, the first-conductivity-type leg, and the second-conductivity-type leg of each of the thermoelectric elements are formed using the same substrate.

6. The array of claim 1, wherein the first-conductivity-type leg is an n-type leg, and the second-conductivity-type leg is a p-type leg.

7. The array of claim 1, wherein the heat absorption layer, the first heat sink layer, and the second heat sink layer are formed by simultaneously forming a first electrode pattern for the heat absorption layer, a second electrode pattern for the first and second heat sink layers, a first leg pattern for the first-conductivity-type leg, and a second leg pattern for the second-conductivity-type leg, and depositing a metal on the first and second electrode patterns.

8. The array of claim 1, wherein the first-conductivity-type leg and the second-conductivity-type leg are formed by simultaneously forming a first electrode pattern for the heat absorption layer, a second electrode pattern for the first and second heat sink layers, a first leg pattern for the first-conductivity-type leg, a second leg pattern for the second-conductivity-type leg, and implanting impurities into the first leg pattern and the second leg pattern.

9. The array of claim 1, wherein each of the first and second leg patterns has a nanowire shape having a width of about 100 nm or less.

10. The array of claim 1, wherein each of the first-conductivity-type leg and the second-conductivity-type leg is formed of a material containing at least one selected from the group consisting of silicon (Si), tellurium (Te), and oxygen (O).

11. The array of claim 1, wherein the heat absorption layer and the first and second heat sink layers are formed of a material containing at least one selected from the group consisting of a doped semiconductor, a metal, and a metal compound.

12. The array of claim 1, wherein an output voltage is controlled according to the number of the thermoelectric elements included in each row or column.

13. The array of claim 1, wherein an output current is controlled according to the number of the thermoelectric elements included in each row or each column.

14. The array of claim 1, wherein output power is controlled according to the number of the thermoelectric elements included in each row or each column.
